(19) United States
(12) Patent Application Publication
(10) Pub. No.: US 2007/0287264 A1
(43) Pub. Date: Dec. 13, 2007

(54) Method and equipment for wafer bonding

(76) Inventor: Tony Rogers, Stroud (GB)

Correspondence Address: COOLEY GODWARD KRONISH LLP;ATTN: Patent Group, Suite 1100, 777 - 6th Street, NW, WASHINGTON, DC, 20001, US

(21) Appl. No.: 11/784,275

(22) Filed: Apr. 5, 2007

Related U.S. Application Data
(63) Continuation-in-part of application No. PCT/GB05/03880, filed on Oct. 10, 2005.

(30) Foreign Application Priority Data
Oct. 9, 2004 (GB) 0422498.6
Oct. 9, 2004 (GB) 0422499.4

(51) Int. Cl. H01L 21/50; B29C 65/00

(52) U.S. Cl. 438/457; 156/349; 257/E21.499

(57) ABSTRACT

A method and apparatus for performing in-situ wafer surface activation, precision alignment of features on each wafer and bonding of the wafers in the same apparatus. The direct bonding part of this processes optionally includes apparatus for the controlled contacting of wafers in order to ensure single point bond initiation without any tooling contact on the surfaces to be bonded.

### CROSS REFERENCE TO RELATED APPLICATIONS

This application is a continuation-in-part of PCT application serial number PCT/GB2005/003880, filed Oct. 10, 2005, which in turn claims priority to Great Britain application numbers 0422498.6 and 0422499.4, both of which were filed on Oct. 9, 2004. The entire contents of each of these references are incorporated by reference herein.

### TECHNICAL FIELD

The present invention generally relates to methods and apparatus for the direct bonding of wafers.

### BACKGROUND INFORMATION

Systems and methods in which two highly polished surfaces are pulled into intimate contact by surface forces, e.g. Van der Waal's forces or hydrogen bonding have been described as early as 1936 by Lord Raleigh. However, it is only in recent years that the technique has found commercial application and is now commonly used as a fabrication step in the fabrication of silicon-on-insulator (SOI) wafers for microelectronics and as a means of achieving more 3-dimensional capability within micro-electro-mechanical devices (MEMS).

Existing equipment for performing an aligned low temperature direct bonding consists of the following:
(a) A process chamber for performing the required surface activation;
(b) An aligner for aligning the wafers and holding them in aligned contact; and
(c) A bond chamber for contacting and heating the wafers to produce a full strength bond.
   In some cases items (a) & (c) or (a) & (b) are combined but this still means that the wafers have to be transferred from one piece of equipment to another in order to perform the full process. It would be desirable if the process steps defined in items (a) to (c) above could all be carried out in a single machine. This would minimize wafer handling and importantly, would also prevent exposure of the activated wafers to the ambient atmosphere in the period between surface activation and contacting.

### SUMMARY OF THE INVENTION

An embodiment of the invention provides a method of direct bonding of two wafers together. The method includes mounting a first wafer on a first platen in a chamber, mounting a second wafer on a second platen in the chamber with a surface of the second wafer facing a surface of the first wafer, and controlling the atmosphere within the chamber. While the wafers are mounted on the platens in the chamber and the atmosphere in the chamber is controlled, the method further includes activating at least one of the facing surfaces of the wafers, aligning the facing surfaces of the wafers, and applying a force to bond the aligned and activated surfaces to each other. The steps of activation, alignment, and bonding of the wafers are all performed in-situ in the same chamber.

Embodiments according to this aspect of the invention can include various features. For example, the steps of activation, alignment, and bonding of the wafers may be carried out while there is a vacuum in the chamber. Alternatively, the steps of activation, alignment, and bonding of the wafers may be carried out while there is a defined gas pressure in the chamber. The defined gas pressure may be provided by gas selected from: oxygen, nitrogen, an inert gas, a hydrocarbon, compound gases, argon, air, and any mixture thereof.

The steps of activation, alignment, and bonding of the wafers may be carried out while there is a vacuum in the chamber and gaseous ambients in the chamber. The gaseous ambients may be provided by a gas selected from: oxygen, nitrogen, an inert gas, a hydrocarbon, compound gases, argon, air, and any mixture thereof.

The step of activation may be performed on both of the facing surfaces. The step of activation may be performed by a plasma treatment. The step of activation may be performed by means of a process selected from: ultra violet radiation, other frequency electromagnetic radiation, energetic ions, and corona discharge. The step of activation may be performed by a source of activation energy which is remote from the wafers.

The step of alignment may be performed by moving one wafer in relation to the other wafer before bringing the wafers into contact. The step of alignment may be performed using visible light for viewing alignment features. The step of alignment may be performed using infra red light for viewing alignment features. The infra red light may be transmitted through the platens or a wafer chuck.

One wafer may be bowed in a controlled manner, without the inclusion of any material between the wafers, such that the step of bonding is initiated in a defined position on the wafers. The bowing of the wafer may be achieved by means of a pin that applies a force to the back surface of at least one of the wafers while the wafer is held at the edges, with no contact to the surface to be bonded. Heaters may be included such that the bond strength of the wafers can be increased via in-situ heating. A variable force may be applied on the pin depending on the thickness of the wafer being bonded.

Holding of the wafer at the edges may be achieved using spring-loaded edge pins. A force on the spring loaded edge pins may be produced by means which are actuated mechanically, pneumatically, hydraulically or electromagnetically. The edge pins may act at points below the center point of a standard SEMI specification “C” edge on the wafer being bonded.

One of the platens may include an array of spring-loaded pads. A plurality of the pads may be located at a height which is above the remainder. This plurality of pads may be supported by relatively weak springs and one of the wafers to be bonded sitting on this plurality of pads. The remainder of the pads that control the bond propagation may be each supported by a relatively strong spring and may be height-adjustable by pre-loading the spring. A height profile of the pads may be adjusted to give a peak at the center. The height profile of the pads may be adjusted to give a peak in a region for which additional force is required in order to overcome a particular surface feature. The particular surface features may be a depression in the surface of one of the wafers to be bonded.

In another example, activation, alignment, and bonding are all performed in-situ.

Another embodiment of the invention provides an apparatus for direct bonding of two, or more, wafers whereby one wafer can be bowed in a controlled manner, without the inclusion of flags between the wafers, such that the bonding is initiated in a defined position on the wafers.

Yet another embodiment provides apparatus for direct bonding of two, or more, wafers whereby a platen or wafer chuck consists of an array of spring-loaded pads.

### BRIEF DESCRIPTION OF THE DRAWINGS

The drawings generally are to illustrate principles of the invention and/or to show certain embodiments according to the invention. The drawings are not to scale. Like reference symbols in the various drawings generally indicate like elements. Each drawing is briefly described below.

FIG. 1 is a schematic diagram depicting a chamber, a means of manipulating wafers in three linear axes and rotation about the z axis, means for activating the surfaces of the wafer, and an optical system for viewing the wafers while they are in the chamber.

FIG. 2 is a schematic diagram depicting a known apparatus for controlling the wafer contacting process such that there is only a single initial contact point.

FIG. 3 depict the apparatus in FIG. 2 as the deformed wafer is brought into contact with the other wafer.

FIG. 4 depicts an apparatus for achieving the controlled initiation of a single bond front using a “flag-less” system.

FIG. 5 depicts a magnified view of the wafer edge.

FIG. 6 depicts a pin chuck.

### DESCRIPTION

This invention concerns the various steps required during the direct bonding of wafers. The invention will be described in terms of bonding silicon wafers but the principle applies no matter what material is used. Direct bonding refers to the process by which two highly polished surfaces are pulled into intimate contact by surface forces, e.g. Van der Waal's forces or hydrogen bonding. This process was first described by Lord Raleigh in 1936. However, it is only in recent years that the technique has found commercial application and is now commonly used as a fabrication step in the fabrication of silicon-on-insulator (SOI) wafers for microelectronics and as a means of achieving more 3-dimensional capability within micro-electro-mechanical devices (MEMS).

The invention also covers the various steps required during the aligned bonding of wafers using low temperature direct bonding processes. “Low temperature direct bonding” refers to processes such as those described in U.S. Pat. No. 6,645,828 to Farrens whereby plasma activation of the wafer surfaces is used to significantly reduce the subsequent annealing temperature required to produce a high strength bond between the two bonded wafers.

Existing equipment for performing an aligned low temperature direct bond consists of the following:
(a) A process chamber for performing the required surface activation;
(b) An aligner for aligning the wafers and holding them in aligned contact; and
(c) A bond chamber for contacting and heating the wafers to produce a full strength bond.
   In some cases items (a) & (c) or (a) & (b) are combined but this still means that the wafers have to be transferred from one piece of equipment to another in order to perform the full process. It would be desirable if the process steps defined in items (a) to (c) above could all be carried out in a single machine. This would minimize wafer handling and importantly, would also prevent exposure of the activated wafers to the ambient atmosphere in the period between surface activation and contacting.

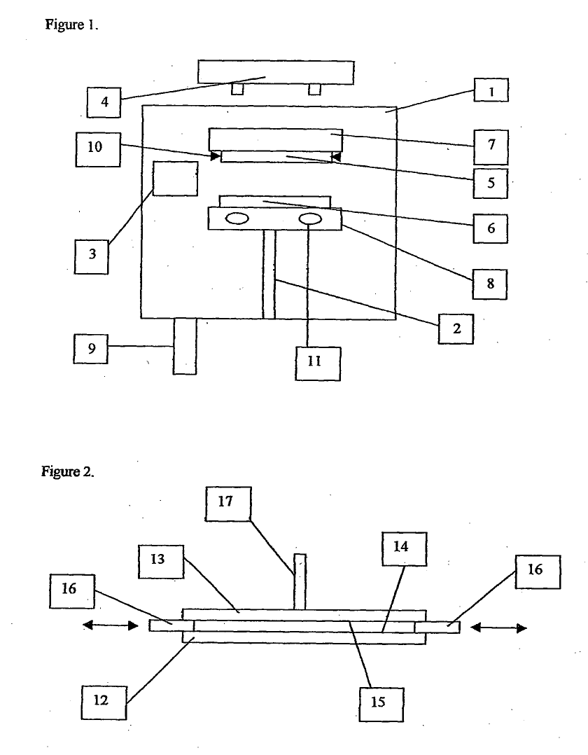

Accordingly this invention provides a means of performing steps (a) to (c) in a single machine. This machine will now be described with reference to the accompanying drawings. The machine shown schematically in FIG. 1 consists of a chamber (1), a means (2) of manipulating the wafers in three linear axes, x, y & z, and rotation about the z axis, a means (3) for activating the surfaces of the wafer, and an optical system (4) for viewing the wafers while they are in the chamber. The wafers (5) and (6) are located on upper platen (7) and lower platen (8).

The process is carried out as follows:

Two wafers (5, 6) are loaded into the machine that can then be evacuated to produce a reduced pressure, and/or filled with a gas to provide a specific gaseous environment inside the chamber. The upper wafer (5) is fixed to the upper platen (7) and is oriented with the surface to be bonded facing downwards. The lower wafer (6) is located on the lower platen (8) and is oriented with the surface to be bonded facing upwards.

Once the required gaseous ambient (gas composition and pressure) has been achieved then the two surfaces to be bonded are activated using the in-situ source. This can be achieved via the striking of a plasma between the two wafers as described in U.S. Pat. No. 6,645,828 to Farrens, or by striking a plasma elsewhere in the chamber and using the gas flow, determined by the position of the port (9) to an external pump, to cause the excited atoms and charged ions that are produced in the remote plasma to pass over the wafer surfaces thereby producing the required surface activation to enable the wafers (5, 6) to subsequently be bonded using a low temperature (typically ˜200° C.). In addition, other techniques such as UV, corona, energetic ions, etc. can be used, the in-situ process being compatible with all these forms of activation.

Having activated the surfaces the wafers (5,6) are then aligned in-situ. This is accomplished by mounting the lower wafer (6) on a moveable (XYZO) stage and holding the other wafer (5) upside down in the vacuum chamber (1). A wafer clamp arrangement uses a spring-loaded knife edge (10) to achieve this upside-down mounting without any part of the fixture protruding beyond the surface of the wafer. The external optics can be used to see, via viewports in the chamber lid, the alignment marks on the two wafers (5, 6). For IR alignment, two IR sources 11 are fitted in the appropriate positions beneath the lower wafer (6).

Once the wafers (5, 6) are aligned, the Z drive is used to bring wafers (5, 6) into contact and to apply force. This produces a bonded interface strong enough for the wafers (5, 6) to then be removed from the chamber (1). Storage at room temperature for 24 hours, or a low temperature anneal, e.g. 2 hours at 300° C., results in a high strength bond. Optionally this heating can also be performed in-situ.

Although the direct bonding step can be performed with flat platens, it is preferable for the bond to be initiated at a single point.

Tools for performing direct bonding, and ensuring a single bond initiation point, are commercially available and all work in a similar fashion. Referring to FIG. 2, the two wafers (12) and (13) to be bonded are mounted in a machine such that the two faces (14) and (15) that require bonding are facing each other. If the wafers (12, 13) were brought into contact without any additional steps being taken then, unless they were perfectly flat and polished to a sub-nm surface finish, they would only actually touch at a few locations. These initial location points would act as the starting points for the surface forces to pull the wafers into intimate contact. We can call this progression of the contact region, from each point, a bond front. The problem with this process is that the multitude of bond fronts results in some of the bond fronts intersecting and this can result in the generation of a non-bonded region, commonly referred to as a void.

In order to overcome the formation of voids it is preferable to control the wafer contacting process such that there is only a single initial contact point, usually but not necessarily, at the center of the wafer. To achieve this controlled wafer contacting, existing equipment utilizes “flags” (16) which are inserted at, normally, three locations around the wafer edges. These flags that are typically about 0.1 mm thick and protrude about a millimeter in from the wafer edge, serve to keep the two wafers a set distance apart.

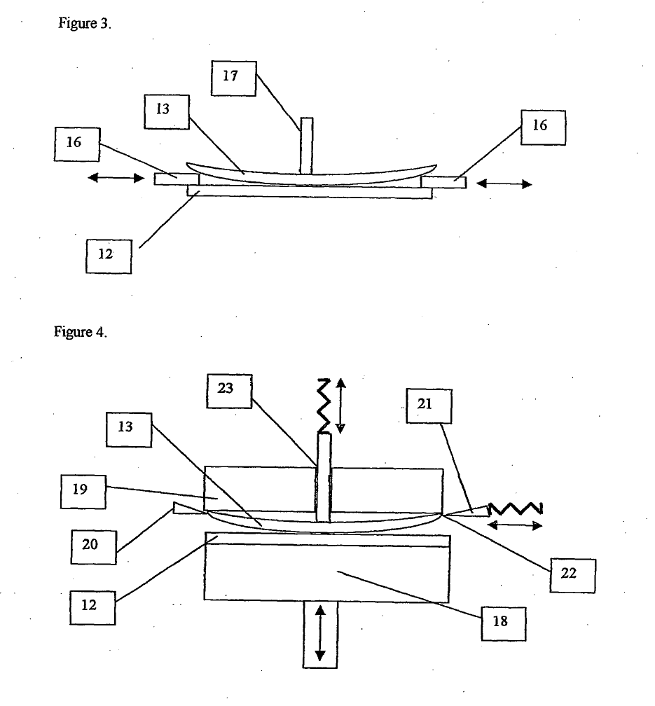

In order to contact the wafers a push-pin or rod (17) is then used to deform one of the wafers such that the center of the deformed wafer is brought into contact with the other wafer. This process is shown in FIG. 3. Once this contact has been made the flags (16) can be withdrawn (as indicated by the arrows) and a single bond front then propagates out radially from the central initiation point, thus preventing the occurrence of voids.

Although this process works well, it does have problems associated with it. For example, it is often desirable in wafer processing for both MEMS and microelectronics processing to avoid mechanical contact with the surfaces to be bonded. Resultant issues such as scratches and the generation of particles can affect yields. In addition, the inclusion of a mechanism for inserting and removing the flags increases the machine complexity, plus the thin flags are prone to failure.

Accordingly, this invention describes a method for achieving the controlled initiation of a single bond front using a “flag-less” system. Referring now to FIG. 4, wafers (12) and (13) are arranged to face each, but instead of flags (16) being used to control the separation of the two wafers, the lower wafer (12) rests on a platen (18) that can be moved in a controlled manner in the Z direction, i. e. perpendicular to the wafer plane. The upper wafer (13) is held on a second platen (19) that incorporates an edge clamping system that holds the wafers in place. This edge clamping system typically consists of three knife-edges, two fixed (20) and one spring-loaded (21), although other quantities of knife-edges, and combinations of fixed vs. spring-loaded knife edges can be used. A typical spring force for the spring-loaded knife-edge is 350 g but other values can be used.

To mount the wafer (13) the spring-loaded knife-edge (21) is withdrawn (as indicated by the arrows) and once the wafer (13) is in place then the spring-loaded knife-edge (21) is released such that the spring force acts on the wafer edge (22). Referring now to FIG. 5 that shows a magnified view of the wafer edge (22) it can be seen that the wafer edge has a “C” shape. This shape is standard for silicon wafers, and many other wafer materials including glass, and is defined as an industry standard by SEMI (Semiconductor Equipment & Materials International). This standard shape helps to support the wafers when using the wafer clamping system described here. Provided that the height of the knife-edges (20, 21), with respect to the platen (19) is greater than 50% of the wafer thickness, then the knife edges (20, 21) not only support the wafer (13) via the spring force, but provide a “ledge” on which the wafer (13) sits without actually making any contact to the surface (15) to be bonded.

Referring back to FIG. 4, having secured the wafer (13) it is now necessary to deform it such that the central part is made to contact the other wafer (12) in a single point, preferably but not necessarily, in the center. To achieve this a further spring-loaded pin (23), or a pin that can be actuated (in the direction indicated by the arrows) by any other means (e.g. shape memory alloy, bimetallic, piezoelectric, electromechanical, etc.) is fixed into the platen (19). This pin is then used to deform the wafer (13) by a fixed amount, typically about 0.1 mm. The other platen (18) is then raised and a force applied that is gradually increased such that it overcomes the force acting on the spring pin (23). In this way the contact area of the two wafers is increased in a controlled manner until full area contact is achieved when the spring-pin (23) is fully compressed. Typically the spring-pin force is about 100N but can be adjusted to suit wafers of different thickness. The force available through the lower platen (18) is much higher than this and in some instances, e.g. to overcome various warps, hollows, rough areas, etc. in either of the two wafer surfaces to be bonded, it may be necessary to apply many kN.

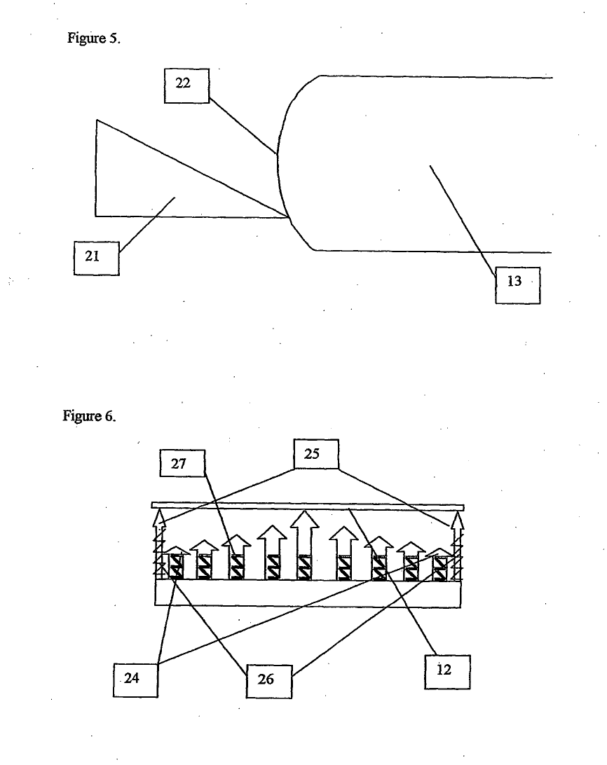

To assist with the controlled bonding of wafers with regions that are more difficult to bring into intimate contact, an alternative to the plane platen (18) can be used. This alternative, known as a pin chuck, is described in FIG. 6. It consists of an array of spring-loaded pins (24). Three (25) of these pins are located at a height which is above the remainder. These three pins are supported by very weak springs (26) (˜10N) and the wafer (12) to be bonded sits on these pins. The rest of the pins are each supported by a much stronger spring (27), typically 100N each, and the heights of these pins can be controlled by pre-loading the springs on the rods. In this manner a controlled profile of pin heights can be obtained. Normally the profile would be adjusted to give a peak at the center. Thus the bond front propagates from the center outwards in a similar manner as for the case of the flat platen, but in the case of the pin chuck the profiles can be adjusted such that force can be concentrated in a region for which additional force is required in order to overcome a particular surface feature, e.g. depression in the surface of one of the wafer to be bonded.

Wafer bonding using the pin chuck works as follows. The three weak springs (25) are levelled such that the wafer (12) can be made parallel to the other wafer (13). The pin chuck is then raised until the two wafers (12) and (13) are in close proximity. Micromanipulators (not shown in the drawings) in the X and Y axes, plus rotation are then used to align the patterns that exist on the two wafers. The wafers are then brought into contact and at this point the highest pin (24) in the array contacts the wafer (12) and starts to work against the opposing spring (23). As the wafer (13) is flattened further pins (24) in the array start acting on the wafer (12) such that the bond front propagation proceeds outwards from the initiation point in a controlled manner.

The tooling described above represents an improvement in the available technology for controlling the direct bonding of wafers. The set of tools described, i.e. edge clamp, spring-pin, and pin chuck, can all be used together for “difficult to bond” wafers, or the edge clamp and spring-pin can be used with a standard flat platen for more ideal wafers. For both cases the drawbacks previously described when using a flag-based system are overcome.

In some circumstances it is also beneficial to include a heater(s) in the platens (18) and (19), or the pin array (24) so that once contacted, the bond strength between the wafers can be increased in-situ via heating.

1. A method of direct bonding of two wafers together, comprising the steps of mounting a first wafer on a first platen in a chamber; mounting a second wafer on a second platen in the chamber with a surface of the second wafer facing a surface of the first wafer; controlling the atmosphere within the chamber; and, while the wafers are mounted on the platens in the chamber and the atmosphere in the chamber is controlled, activating at least one of the facing surfaces of the wafers, aligning the facing surfaces of the wafers, and applying a force to bond the aligned and activated surfaces to each other, whereby the steps of activation, alignment and bonding of the wafers are all performed in-situ in the same chamber.

2. A method as claimed in claim 1, wherein the steps of activation, alignment and bonding of the wafers are carried out while there is a vacuum in said chamber.

3. A method as claimed in claim 1, wherein the steps of activation, alignment and bonding of the wafers are carried out while there is a defined gas pressure in said chamber.

4. A method as claimed in claim 3, wherein the defined gas pressure is provided by a gas selected from: oxygen, nitrogen, an inert gas, a hydrocarbon, compound gases, argon, air, and any mixture thereof.

5. A method as claimed in claim 1, wherein the steps of activation, alignment and bonding of the wafers are carried out while there is a vacuum in said chamber and gaseous ambients in said chamber.

6. A method as claimed in claim 5, wherein the gaseous ambients are provided by a gas selected from: oxygen, nitrogen, an inert gas, a hydrocarbon, compound gases, argon, air, and any mixture thereof.

7. A method as claimed in claim 1, wherein the step of activation is performed on both of the facing surfaces.

8. A method as claimed in claim 1, wherein the step of activation is performed by a plasma treatment.

9. A method as claimed in claim 1, wherein the step of activation is performed by means of a process selected from: ultra violet radiation, other frequency electromagnetic radiation, energetic ions, and corona discharge.

10. A method as claimed in claim 1, wherein the step of activation is performed by a source of activation energy which is remote from the wafers.

11. A method as claimed in claim 1, wherein the step of alignment is performed by moving one wafer in relation to the other wafer before bringing the wafers into contact.

12. A method as claimed in claim 1, wherein the step of alignment is performed using visible light for viewing alignment features.

13. A method as claimed in claim 1, wherein the step of alignment is performed using infra red light for viewing alignment features.

14. A method as claimed in claim 13, wherein the infra red light, is transmitted through the platens.

15. A method as claimed in claim 13, wherein the infra red light, is transmitted through a wafer chuck.

16. A method as claimed in claim 1, wherein one wafer is bowed in a controlled manner, without the inclusion of any material between the wafers, such that the step of bonding is initiated in a defined position on the wafers.

17. A method as claimed in claim 16, wherein the bowing of the wafer is achieved by means of a pin that applies a force to the back surface of at least one of the wafers while the wafer is held at the edges, with no contact to the surface to be bonded.

18. A method as claimed in claim 17, wherein heaters are included such that the bond strength of the wafers can be increased via in-situ heating.

19. A method as claimed in claim 17, wherein a variable force is applied on the pin depending on the thickness of the wafer being bonded.

20. A method as claimed in claim 17, wherein holding of the wafer at the edges is achieved using spring-loaded edge pins.

21. A method as claimed in claim 20 wherein a force on the spring loaded edge pins is produced by means which are actuated mechanically, pneumatically, hydraulically or electromagnetically.

22. A method as claimed in claim 20, wherein the edge pins act at points below the center point of a standard SEMI specification “C” edge on the wafer being bonded.

23. A method as claimed in claim 1, wherein one of the platens includes an array of spring-loaded pads.

24. A method as claimed in claim 23, wherein a plurality of the pads are located at a height which is above the remainder, this plurality of pads being supported by relatively weak springs and one of the wafers to be bonded sitting on this plurality of pads; and wherein the remainder of the pads, that control the bond propagation, are each supported by a relatively strong spring and are height-adjustable by pre-loading the spring.

25. A method as claimed in claim 24, wherein a height profile of the pads is adjusted to give a peak at the center.

26. A method as claimed in claim 24, wherein the height profile of the pads is adjusted to give a peak in a region for which additional force is required in order to overcome a particular surface feature.

27. A method as claimed in claim 26, wherein the particular surface features is a depression in the surface of one of the wafers to be bonded.

28. Wafer bonding apparatus whereby activation, alignment and bonding are all performed in-situ.

29. Apparatus for direct bonding of two, or more, wafers whereby one wafer can be bowed in a controlled manner, without the inclusion of flags between the wafers, such that the bonding is initiated in a defined position on the wafers.

30. Apparatus for direct bonding of two, or more, wafers whereby a platen or wafer chuck consists of an array of spring-loaded pads.
